(19) United States
(12) Patent Application Publication
(10) Pub. No.: US 2012/0127770 A1
(43) Pub. Date: May 24, 2012

(54) Solar Energy AC Generating Apparatus

(75) Inventor: Hyoung-Gurn Kim, Daejeon (KR)

(73) Assignee: TOPSUN CO., LTD., Jangseong-Gun, Jeollanam-do (KR)

(21) Appl. No.: 13/380,653

(22) PCT Filed: Jul. 2, 2010
(86) PCT No.: PCT/KR2010/004329

§ 371 Date: Feb. 2, 2012

(30) Foreign Application Priority Data
Jul. 2, 2009 (KR) 10-2009-0060053

(51) Int. Cl. H05K 7/20

(52) U.S. Cl. 363/141

(57) ABSTRACT

A solar AC power generation apparatus is provided such that it can be conveniently installed in accordance with a required power generation amount because utility power can be drawn from each solar cell panel having a predetermined generation capacity. The solar AC power generation apparatus includes: a solar cell panel comprising a plurality of cells arranged in a certain pattern and serially connected to each other in units of two or more cells, upper and lower sheets protecting the plurality of cells from the outside, a transparent resin filled between the sheets, and an edge frame installed along the circumference of the edges of the sheets; an external terminal box fixed to the solar cell panel and for drawing out the DC power of a solar cell module including a plurality of cells connected in series; and an inverter device for converting the DC power drawn from the external terminal box into AC power and outputting the AC power.

### TECHNICAL FIELD

The present invention relates to a solar AC power generation apparatus. More particularly, the present invention relates to a solar AC power generation apparatus, which enables each solar cell panel having a predetermined generation capacity to draw utility power.

### BACKGROUND ART

In general, fossil fuels such as petroleum, coal, gas, etc. have been widely used as energy sources in line with the development of human society. With the rise of problems such as environmental pollution and depletion of fossil fuels, however, the need for new and renewable energies is increasing.

Solar energy, one of the new renewable energies, which is known as an infinite energy source, has been used for real life in such a manner that heating and hot water supply are carried out using radiant heat or energy of solar light is converted into electrical energy.

As means for converting energy of solar light into electrical energy, a solar power generation system is widely used, which converts DC power obtained from a solar cell into AC power by an inverter or the like and supplies the AC power to various loads (for example, electronic products).

Solar cells used for the aforementioned solar power generation system are commonly used in the form of a solar cell module comprising cells connected in series and in parallel, each cell having a generation capacity of approximately 1.5 W as the smallest unit for generating electricity or in the form of a solar cell array comprising a number of solar cell modules assembled in series and in parallel.

In an example, a conventional solar power generations system commonly used at home comprises a support frame mainly installed on the rooftop or roof of a house, a plurality of solar cell modules (or referred to as a “solar cell array”) each supported and arranged on the support frame, a current collection box for collecting DC power output from each of the solar cell modules, and an inverter connected to a load or the like and for converting the power collected by the current collection box.

In the above, each solar cell module comprises a plurality of cells arranged and supported in EVA resin or the like so as to obtain a predetermined voltage and current. A front sheet made of transparent glass is installed at the front of a cell, a back sheet made of a transparent or opaque glass plate or synthetic resin plate is installed at the rear thereof, a peripheral frame is installed along the edges thereof, and an external terminal is installed on the outer surface of the back sheet.

However, it is difficult for the conventional solar power generation system having the above-described configuration to show optimal generation performance if some of the plurality of solar cell modules have different outputs from each other.

Moreover, there is any failure or performance degradation in the inverter, the overall performance of the system may be degraded. Thus, a solution for this problem is required.

The above information disclosed in this Background section is only for enhancement of understanding of the background of the invention and therefore it may contain information that does not form the prior art that is already known in this country to a person of ordinary skill in the art.

### DISCLOSURE

### Technical Problem

The present invention has been made in an effort to provide a solar AC power generation apparatus, which offers high efficiency because it is rendered usable by drawing utility power directly from a solar cell panel having a predetermined generation capacity, and which makes on-the-spot construction and handling convenient because an external terminal box and an inverter circuit are integrally formed with the solar cell panel.

### Technical Solution

An exemplary embodiment of the present invention provides a solar AC power generation apparatus including: a solar cell panel; an external terminal box fixed to the solar cell panel and for drawing out the DC power of a solar cell module including a plurality of cells connected in series; and an inverter device for converting the DC power drawn from the external terminal box into AC power and outputting the AC power.

The solar cell panel includes: a plurality of cells arranged in a certain pattern and serially connected to each other in units of two or more cells, upper and lower sheets protecting the plurality of cells from the outside, a transparent resin filled between the sheets, and an edge frame installed along the circumference of the edges of the sheets.

The upper sheet is made of a transparent glass plate.

The lower sheet is made of a transparent or opaque glass plate or a synthetic resin plate.

The edge frame includes: an upper horizontal portion fixed in an overlapping manner to an edge of the upper sheet; a vertical portion vertically bent from an end portion of the upper horizontal portion; and a lower horizontal portion, which is bent at a right angle from an end portion of the vertical portion in parallel to the upper horizontal portion, and whose inner surface faces the inner surface of the lower sheet at a certain distance from the lower sheet.

The edge frame may be formed of any one of stainless steel, aluminum, and copper.

The external terminal box is fixed to the lower sheet of the solar cell panel.

The external terminal box has a connection terminal installed therein, whose one end portion is electrically connected to the solar cell module and whose other end portion is electrically connected to the inverter device.

The inverter device includes: a protection case formed in a rectangular box shape and having a plurality of heat radiation protrusions projected at predetermined intervals on its surface; and an inverter circuit electrically connected to the connection terminal of the external terminal box and for converting DC power input through an input terminal into AC power and drawing the AC power via an output terminal.

The protection case is tightly contacted and fixed to an outer side of the external terminal box.

In the above, the protection case may be made of any one of stainless steel, aluminum, and copper, and the external terminal box may be made of stainless steel, aluminum, and copper.

The plurality of heat radiation protrusions may be projected at predetermined intervals on at least one of the outer and inner surfaces of the external terminal box.

The other end portion of the connection terminal and the input terminal of the inverter device may include a pair of sockets that are coupled to be separable from each other.

Moreover, the protection case of the inverter device may be tightly contacted and fixed to the edge frame.

In the above, the protection case may be tightly contacted and fixed to the inside of the lower horizontal portion and vertical portion of the edge frame.

In addition, a plurality of heat radiation protrusions may be projected at predetermined intervals on the outer surface of the external terminal box, a connection terminal connected to the solar cell module may be installed inside the external terminal box, and the inverter device may be integrally fixed to the inside of the external terminal box and include an inverter circuit electrically connected to the connection terminal and for converting input DC power into AC power.

### ADVANTAGEOUS EFFECTS

In accordance with the solar AC power generation apparatus according to the present invention, utility power can be drawn from each solar cell panel. Thus, high efficiency can be achieved when small-scale electric power is required, and the number of solar cell plates can be determined in accordance with a required power generation amount, or solar cell panels with varying generation capacity can be selected, combined, and conveniently installed and used.

Also, in accordance with the solar AC power generation apparatus according to the present invention, transportation, storage, construction, etc. can be made convenient and easy because each part is assembled into a structure of one assembly.

Moreover, in accordance with the solar AC power generation apparatus according to the present invention, it is possible to prevent any failure or performance degradation and improve durability because heat generation temperature can be lowered using heat radiation protrusions.

In addition, the solar AC power generation apparatus according to the present invention improves assembling properties and makes maintenance and repair including part replacement more convenient and easier because the external terminal box and the inverter can be easily separated from and coupled to each other.

Furthermore, in accordance with the solar AC power generation apparatus according to the present invention, when problems occur, such as when no power is generated from some of the plurality of solar cell panels or when the power generation amount is reduced, this does not affect the power generation of the remaining solar cell panels. Therefore, it is possible to minimize generation loss and, overall, effectively prevent the stopping of power generation.

Furthermore, in accordance with the solar AC power generation apparatus according to the present invention, power generation state can be monitored. Therefore, it is possible to easily detect defects such as generation performance degradation or failure in a module, cell, or array and take quick measures.

In accordance with the solar AC power generation apparatus according to the present invention, utility power can be drawn from each solar cell panel. Thus, high efficiency can be achieved when small-scale electric power is required, and the number of solar cell plates can be determined in accordance with a required power generation amount, or solar cell panels with varying generation capacity can be selected, combined, and conveniently installed and used.

Also, in accordance with the solar AC power generation apparatus according to the present invention, transportation, storage, construction, etc. can be made convenient and easy because each part is assembled into a structure of one assembly.

Moreover, in accordance with the solar AC power generation apparatus according to the present invention, it is possible to prevent any failure or performance degradation and improve durability because heat generation temperature can be lowered using heat radiation protrusions.

In addition, the solar AC power generation apparatus according to the present invention improves assembling properties and makes maintenance and repair including part replacement more convenient and easier because the external terminal box and the inverter can be easily separated from and coupled to each other.

Furthermore, in accordance with the solar AC power generation apparatus according to the present invention, when problems occur, such as when no power is generated from some of the plurality of solar cell panels or when the power generation amount is reduced, this does not affect the power generation of the remaining solar cell panels. Therefore, it is possible to minimize generation loss and, overall, effectively prevent the stopping of power generation.

Furthermore, in accordance with the solar AC power generation apparatus according to the present invention, power generation state can be monitored. Therefore, it is possible to easily detect defects such as generation performance degradation or failure in a module, cell, or array and take quick measures.

### DESCRIPTION OF THE DRAWINGS

FIG. 1 is an exploded perspective view showing a solar AC power generation apparatus according to one exemplary embodiment of the present invention.

FIG. 2 is a bottom perspective view showing a solar AC power generation apparatus according to one exemplary embodiment of the present invention.

FIG. 3 is a cross-sectional view showing a solar AC power generation apparatus according to one exemplary embodiment of the present invention.

FIG. 4 is a partial enlarged plan view showing a solar cell module in the solar AC power generation apparatus according to one exemplary embodiment of the present invention.

FIG. 5 is a perspective view showing an inverter device being coupled to an external terminal box to be vertically separable from each other in the solar AC power generation apparatus according to one exemplary embodiment of the present invention.

FIG. 6 is a bottom perspective view showing the inverter device being installed on an edge frame of a solar cell panel in the solar AC power generation apparatus according to one exemplary embodiment of the present invention.

FIG. 7 is a partial enlarged cross-sectional view showing the inverter device being installed on the edge frame of the solar cell panel in the solar AC power generation apparatus according to one exemplary embodiment of the present invention.

FIG. 8 is a bottom perspective view showing a solar AC power generation apparatus according to another exemplary embodiment of the present invention.

### MODE FOR INVENTION

Next, a solar AC power generation apparatus according to an exemplary embodiment of the present invention will be described in detail with reference to the accompanying drawings.

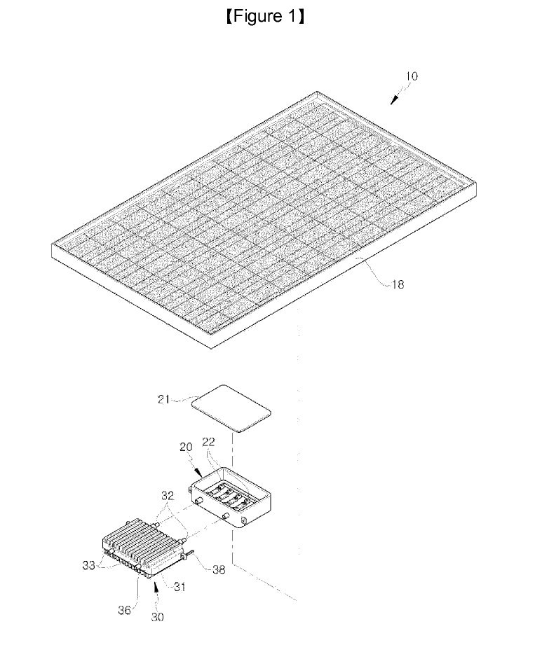

First, as shown in FIGS. 1 and 2, the solar AC power generation apparatus according to an exemplary embodiment of the present invention includes a solar cell panel 10, an external terminal box 20 fixed to the solar cell panel 10, and an inverter device 30.

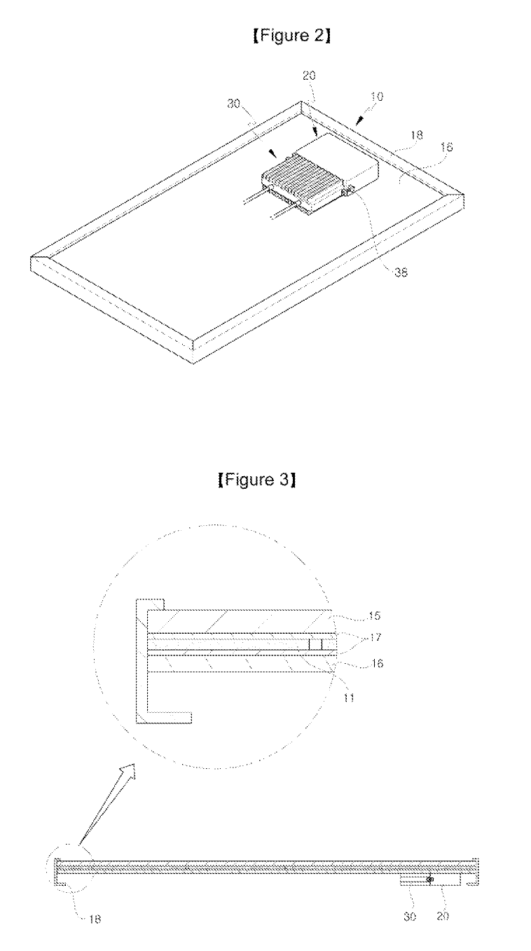

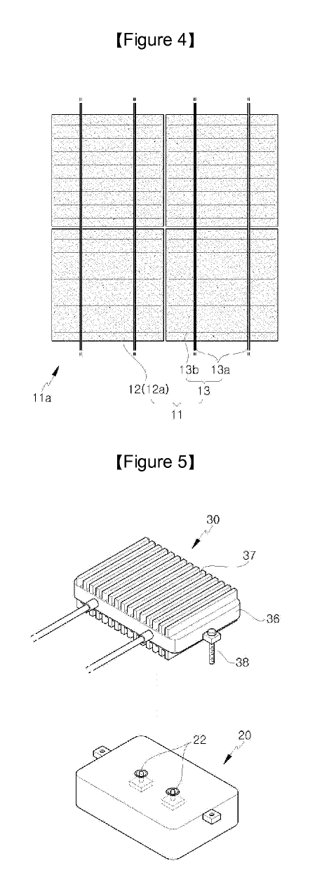

As shown in FIGS. 3 and 4, the solar cell panel 10 includes a plurality of cells 11 arranged in a certain pattern and serially connected to each other, upper and lower sheets 15 and 16 protecting the plurality of cells 11 from the outside, a transparent resin 17 filled between the upper sheet 15 and the lower sheet 16, and an edge frame installed along the circumference of the edges of the sheets 15 and 16.

Each of the cells 11 includes a semiconductor device 12 provided with a light receiving surface 12a absorbing light and photoelectrically converting the light to generate an electric charge and an electrode 13 arranged on the light receiving surface 12a of the device 12.

The electrode 13 includes a pair of bus bars 13a disposed on both sides of the light receiving surface 12a and a plurality of current collecting electrodes electrically connected to the bus bars 13a.

The upper sheet 15 is made of a transparent glass plate.

The lower sheet 16 is made of a transparent or opaque glass plate or a synthetic resin plate.

As shown in FIG. 7, the edge frame 18 includes an upper horizontal portion 18a fixed in an overlapping manner to an edge of the upper sheet 15, a vertical portion 18b vertically bent from an end portion of the upper horizontal portion 18a, and a lower horizontal portion 18c, which is bent at a right angle from an end portion of the vertical portion 18b in parallel to the upper horizontal portion 18a, and whose inner surface faces the inner surface of the lower sheet 16 at a certain distance from the lower sheet 16.

The edge frame 18 can be formed of any one of stainless steel, aluminum, and copper.

The above-described solar cell panel 10 can be embodied in the same way as a generally and widely used solar cell panel, so a detailed description thereof will be omitted.

The external terminal box 20 is fixed to the lower sheet 16 of the solar cell panel 10, and draws the DC power of the solar cell module 11 a including the plurality of cells 11 connected in series to the outside.

In the above, the external terminal box 20 is formed in an approximately box shape, and has a connection terminal 22 installed therein, whose one end portion is electrically connected to the solar cell module 11 a and whose other end portion is electrically connected to the inverter device 30.

The pair of bus bars 13a can be electrically connected to the connection terminal 22.

The external terminal box 20 is opened at one surface, and a cover 21 is installed on the opened surface.

The inverter device 30 is configured to convert DC power drawn through the external terminal box 20 into AC power and output the AC power.

The inverter device 30 includes a protection case 36 formed in an approximately rectangular box shape and having a plurality of heat radiation protrusions 37 projected at predetermined intervals on its surface and an inverter circuit 31 electrically connected to the connection terminal 22 of the external terminal box 20 and for converting DC power input through an input terminal 32 into AC power and drawing the AC power via an output terminal 33.

The protection case 36 of the inverter device 30 is tightly contacted and fixed to one side of the external terminal box 20.

In the above, the protection case 36 and the external terminal box 20 may be formed of any one of stainless steel, aluminum, and copper.

Through not shown in the drawings, the plurality of heat radiation protrusions may be projected at predetermined intervals on at least one of the outer and inner surfaces of the external terminal box 20.

As shown in FIG. 5, the protection case 36 of the inverter device 30 may be tightly contacted and fixed to the external terminal box 20 in a laminated manner.

The protection case 36 of the inverter device 30 and the external terminal box 20 are clamped by a clamping screw 38 or the like.

In the case that the protection case 36 of the inverter device 30 is tightly contacted and fixed to the external terminal box 20 as described above, the other end portion of the connection terminal 22 and the input terminal 32 of the inverter device 30 may include a pair of sockets that are coupled to be separable from each other.

In the above, although the connection terminal 22 and the input terminal 32 are not shown in the drawings, they may include a plug and a socket.

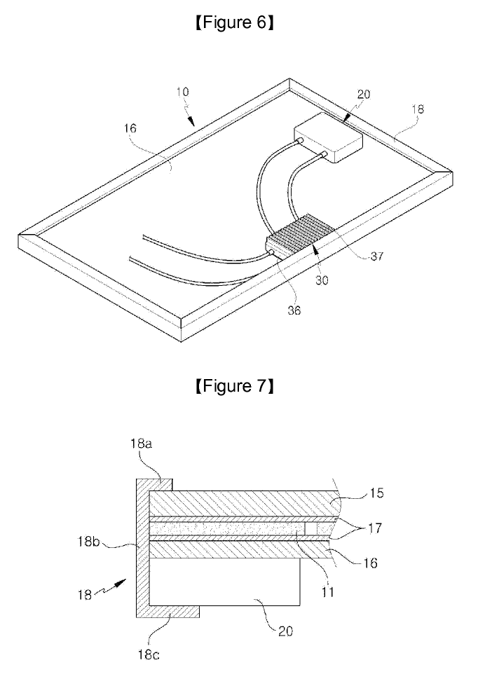

In one exemplary embodiment of the solar AC power generation apparatus according to the present invention, as shown in FIGS. 6 and 7, the protection case 36 of the inverter device 30 may be tightly contacted and fixed to the edge frame 18 of the solar cell panel 10.

For example, the protection case 36 may be tightly contacted and fixed to the inside of the lower horizontal portion 18c and vertical portion 18b of the edge frame 18.

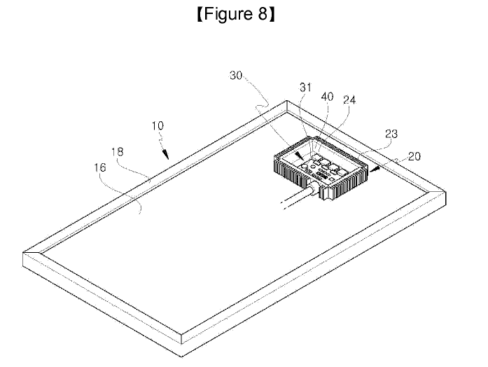

Moreover, in another exemplary embodiment of the solar AC power generation apparatus according to the present invention, as shown in FIG. 8, a plurality of plate-shaped heat radiation protrusions 23 may be projected at predetermined intervals on the outer surface of the external terminal box 20, a connection terminal 24 connected to the solar cell module 11 a may be installed inside the external terminal box 20, and the inverter device 30 may be integrally fixed to the inside of the external terminal box 20 and include an inverter circuit 31 electrically connected to the connection terminal 24 and for converting input DC power into AC power.

The external terminal box 20 may be formed in the shape of a box opened at one surface, a cover (not shown) may be installed on the opened surface, and heat radiation protrusions 23 may be installed on the cover.

A rectifying diode 40 may be further installed between the inverter circuit 31 and the connection terminal 24.

The above-described solar cell panel 10 can be embodied in the same way as a generally and widely used solar cell panel, so a detailed description thereof will be omitted.

While this invention has been described in connection with what is presently considered to be the most practical and preferred embodiments, the present invention is not limited thereto. Various variations may be realized within the appended claims, detailed description of the present invention, and the drawings, and consequently, such variations should be understood to be within the scope of the present invention.

### INDUSTRIAL APPLICABILITY

The present invention relates to a solar AC power generation apparatus. More particularly, the present invention relates to a solar AC power generation apparatus, which enables each solar cell panel having a predetermined generation capacity to draw utility power.

1. A solar AC power generation apparatus comprising:
a solar cell panel comprising a plurality of cells arranged in a certain pattern and serially connected to each other in units of two or more cells, upper and lower sheets protecting the plurality of cells from the outside, a transparent resin filled between the sheets, and an edge frame installed along the circumference of the edges of the sheets;
an external terminal box fixed to the solar cell panel for drawing out the DC power of a solar cell module including a plurality of cells connected in series; and
an inverter device for converting the DC power drawn from the external terminal box into AC power and outputting the AC power,
wherein the inverter device comprises: a protection case formed in a rectangular box shape and having a plurality of heat radiation protrusions projected at predetermined intervals on its surface; and an inverter circuit electrically connected to the connection terminal of the external terminal box and for converting DC power input through an input terminal into AC power and drawing the AC power via an output terminal.

2. The solar AC power generation apparatus of claim 1, wherein the protection case of the inverter device is tightly contacted and fixed to an outer surface of the external terminal box.

3. The solar AC power generation apparatus of claim 2, wherein the external terminal box has a connection terminal installed therein, whose one end portion is electrically connected to the solar cell module and whose other end portion is electrically connected to the inverter device, and
the other end portion of the connection terminal and the input terminal of the inverter device may include a pair of sockets that are coupled to be separable from each other.

4. The solar AC power generation apparatus of claim 1, wherein the protection case of the inverter device is made of any one of stainless steel, aluminum, and copper.

5. The solar AC power generation apparatus of claim 1, wherein the external terminal box is made of any one of stainless steel, aluminum, and copper.

6. The solar AC power generation apparatus of claim 1, wherein the plurality of heat radiation protrusions are projected at predetermined intervals on at least one of the outer and inner surfaces of the external terminal box.

7. The solar AC power generation apparatus of claim 1, wherein the upper sheet is made of a transparent glass plate,
the lower sheet is made of a transparent or opaque glass plate or a synthetic resin plate,
the edge frame includes: an upper horizontal portion fixed in an overlapping manner to an edge of the upper sheet; a vertical portion vertically bent from an end portion of the upper horizontal portion; and a lower horizontal portion, which is bent at a right angle from an end portion of the vertical portion in parallel to the upper horizontal portion, and whose inner surface faces the inner surface of the lower sheet at a certain distance from the lower sheet, and
the protection case is tightly contacted and fixed to the inside of the lower horizontal portion and vertical portion of the edge frame.

8. The solar AC power generation apparatus of claim 7, wherein the edge frame of the solar cell panel is made of any one of stainless steel, aluminum, and copper.

9. The solar AC power generation apparatus of claim 1, wherein a plurality of plate-shaped heat radiation protrusions are projected at predetermined intervals on the outer surface of the external terminal box,
a connection terminal connected to the solar cell module is installed inside the external terminal box, and
the inverter device is integrally fixed to the inside of the external terminal box and includes an inverter circuit electrically connected to the connection terminal for converting input DC power into AC power.
